(19) United States
(12) Patent Application Publication
(10) Pub. No.: US 2012/0238064 A1
(43) Pub. Date: Sep. 20, 2012

(54) ENHANCEMENT-MODE HIGH-ELECTRON-MOBILITY TRANSISTOR AND THE MANUFACTURING METHOD THEREOF

(75) Inventors: EDWARD YI CHANG, Hsinchu (TW); Chia-Hua Chang, Hsinchu (TW); Yueh-Chin Lin, Hsinchu (TW)

(73) Assignee: National Chiao Tung University, Hsinchu (TW)

(21) Appl. No.: 13/487,711

(22) Filed: Jun. 4, 2012

Related U.S. Application Data
(62) Division of application No. 12/894,384, filed on Sep. 30, 2010.

(30) Foreign Application Priority Data
Jul. 27, 2010 (TW) 099124686

(51) Int. Cl. H01L 21/335

(52) U.S. Cl. 438/172; 257/E21.403

(57) ABSTRACT

This invention discloses an enhancement-mode high-electron-mobility transistor and the manufacturing method thereof. The transistor comprises an epitaxial buffer layer on a substrate, a source and drain formed in the buffer layer, a PN-junction stack formed on the buffer layer and located between the source and drain, and a gate formed on the PN-junction stack, wherein the PN-junction stack is composed of alternating layers of a P-type semiconductor and an N-type semiconductor.

### CROSS REFERENCE TO RELATED PATENT APPLICATION

This application is a divisional of an application Ser. No. 12/894,384, filed on Sep. 30, 2010.

### TECHNICAL FIELD

The present disclosure relates to an integrated-circuit high-electron-mobility transistor (HEMT) device, and more particularly, to an enhancement-mode HEMT with a PN-junction stack to increase threshold voltages of the transistor.

### TECHNICAL BACKGROUND

Due to advantageous characteristics of the GaN HEMT, such as high output power, high breakdown voltage, and resistance to high temperature, it has been widely used in the field of high-power applications. However, there are many polarized carriers, configured to form the two-dimensional electron gas (2DEG), in the AlGaN/GaN heterostructural buffer layer of the device. In this circumstance, the transistor generally operates in the depletion mode; that is, the transistor has a negative threshold voltage and operates normally on. The transistor will be turned on even though it is biased at zero gate voltage. This, in turn, causes additional power dissipation in circuits and abnormal turning-on or reaction of high-power semiconductor devices.

The consciousness of environmental protection promotes the rapid development in the field of the electric vehicle, in which high-power HEMTs play an essential role in the electrical circuit. The electrical circuits in vehicles usually operate at a high bias voltage, where the circuits are subject to transient voltage impulses, so the transistors tend to be turned on unpredictably. Although several techniques, such as the normally-off HEMTs of the deeply-recessed-gate structure or by the CF₄ plasma treatment, were proposed to alleviate the forgoing problems, the threshold voltage of the transistors can be increased to at most 0.9V, which still can not meet the requirements of practical circuits. Moreover, both the surface etching process for the deeply-recessed-gate structure and the fluorine-ion implantation process of for the CF₄ plasma treatment may intensify the surface state density of the transistors and, thus, degrade their performance and reliability.

### TECHNICAL SUMMARY

According to one aspect of the present invention, there is provided an enhancement-mode HEMT comprising a buffer layer epitaxially formed on a semiconductor substrate, a source and drain formed on the buffer layer, a PN-junction stack formed on the buffer layer and located between the source and drain, and a gate formed on the PN-junction stack porous metal substrate, wherein the PN-junction stack is composed of alternating layers of a P-type semiconductor and an N-type semiconductor.

According to another aspect of the present invention, there is further provided a method for fabricating an enhancement-mode HEMT comprising providing a semiconductor substrate that is with a buffer layer thereon, forming a PN-junction stack on the buffer layer, etching the PN-junction stack that is out of the predetermined area of a gate, forming a source on one side of the PN-junction stack and a drain on the other side thereof on the buffer layer, and forming the gate on the PN-junction stack, wherein the PN-junction stack is composed of alternating layers of a P-type semiconductor and an N-type semiconductor.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic diagram showing the architecture of an enhancement-mode HEMT according to an embodiment of the present disclosure.

FIG. 2 is a flowchart of a fabricating method of the enhancement-mode HEMT according to another embodiment of the present disclosure.

FIGS. 3-9 are schematic diagrams respectively showing the architectures of the embodiment in the fabrication process.

### DESCRIPTION OF THE EXEMPLARY EMBODIMENTS

For further understanding and recognizing the fulfilled functions and structural characteristics of the disclosure, several exemplary embodiments cooperating with detailed description are presented as the following.

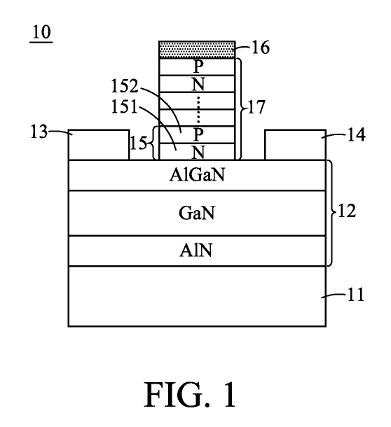

Please refer to FIG. 1, which is a schematic diagram showing the architecture of an enhancement-mode HEMT according to an embodiment of the present disclosure. The enhancement-mode HEMT 10 comprises a semiconductor substrate 11 with a buffer layer 12, a source 13 and drain 14, a PN-junction stack 17, and a gate. The semiconductor substrate 11 is used as a base to build up integrated-circuit devices. The substrate 11 can be GaAs, GaN, Si, SiC, Sapphire, or other semiconductor materials. The buffer layer 12 is formed of GaAs, GaN, MN, or AlGaN, and on the semiconductor substrate 11 by the epitaxy method. A layered structure of buffer layer, AlGaN/GaN/AlN, is used in the embodiment, but is not limited thereby, which can be other single-layer or multi-layer structures. A well is formed in the AlGaN sub-layer to provide an active region of a field-effect transistor or to layout other semiconductor devices. The buffer layer 12 is also used to moderate the mismatch of crystal lattice between the substrate and the active region for semiconductor devices. The source 13 and drain 14 are formed on the buffer layer 12 and can be composed of Ti, Al, W, Ni, or Au.

To increase threshold voltages of enhancement-mode HEMTs effectively, the PN-junction stack 17 composed of alternating layers of a P-type semiconductor 152 and an N-type semiconductor 151 is formed on the buffer layer 12. The upper side of a single PN junction 15 is of P-type, and the lower side is of N-type. The PN junctions are formed of GaAs, GaN, AlN, or AlGaN by the epitaxial or the CVD (chemical vapor deposition) processes, but is not limited thereby, which can be other semiconductor materials or fabrication processes. Because a built-in potential of a PN junction 15 is about 0.7V, when it connects to a field-effect transistor in series, the threshold voltage to turn on the transistor can be increased by about 0.7V. However, to prevent an enhancement-mode HEMT from being turned on irregularly, an enhancement-mode HEMT of high threshold voltage is in need. In the embodiment, a PN-junction stack 17 with M PN junctions on the buffer layer 12 can increase threshold voltage of the enhancement-mode HEMT 10 by M times of 0.7V, or 0.7MV. For example, if the required threshold voltage of a transistor is 50V, 72 PN junctions can be stacked by alternating P-type and N-type semiconductor layers on the buffer layer 12. The amount M of the PN junctions is designated according to practical requirements of various applications. At last, the gate 16 is formed on the PN-junction stack to complete a HEMT that is with high threshold voltages. Material of the gate 16 can be selected from the group consisting of Pb, Al, Ti, Au, WN₂, or mixtures thereof. In the embodiment, the PN-junction stack is separate from the source and drain.

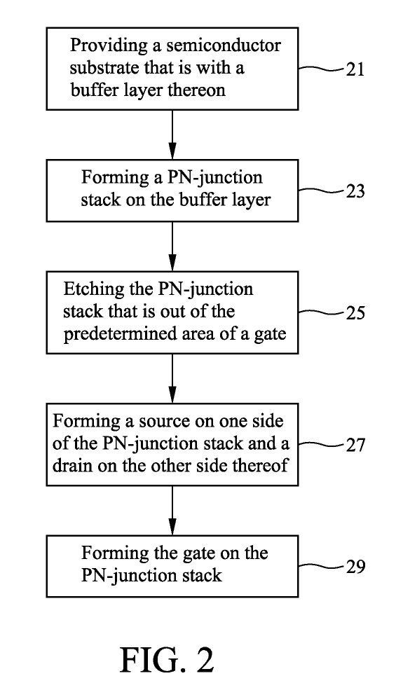

Referring to FIG. 2, a flowchart of a fabricating method of the enhancement-mode HEMT is schematically shown according to another embodiment of the present disclosure. In Step 21, a semiconductor substrate 11 having a buffer layer 12 thereon is provided. The semiconductor substrate 11, used as a base to build up integrated-circuit devices, can be composed of GaAs, GaN, Si, SiC, Sapphire, or other semiconductor materials. The buffer layer 12 is formed of GaAs, GaN, AlN, AlGaN, or multiple sub-layers of the foregoing materials, by the epitaxy method. A dual-layered structure of buffer layer, AlGaN/GaN, is used in the embodiment, but is not limited thereby, which can be other single-layer or multi-layer structures such as AlGaN/GaN/AlN and GaN/AlGaN/AlN/GaN/AlN. Next in Step 23, a PN-junction stack 17 is formed on the buffer layer, wherein each PN junction 15 is composed of a P-type 152 and N-type 151 semiconductor layers, and the PN-junction stack 17 is a stack of alternating layers of a P-type semiconductor and an N-type semiconductor. The PN junctions are formed of GaAs, GaN, AlN, or AlGaN by the epitaxial or the CVD (chemical vapor deposition) processes, but is not limited thereby, which can be other semiconductor materials or fabrication processes. Then in Step 25, the photolithography process is used to etch the PN-junction stack 17 that is out of the predetermined area of a gate. Then in Step 27, a source 13 and drain 14 are formed on the two respective sides of the PN-junction stack 17 and on the buffer layer 12. The source and drain can be composed of Ti, Al, W, Ni, or Au. Finally in Step 29, the gate is formed on the PN-junction stack 17. Material of the gate 16 can be selected from the group consisting of Pb, Al, Ti, Au, WN₂, or mixtures thereof. Also in the embodiment, the PN-junction stack is separate from the source and drain.

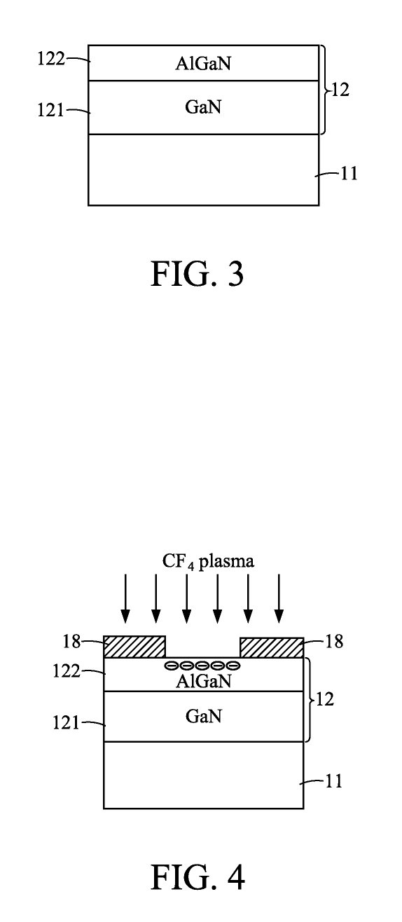

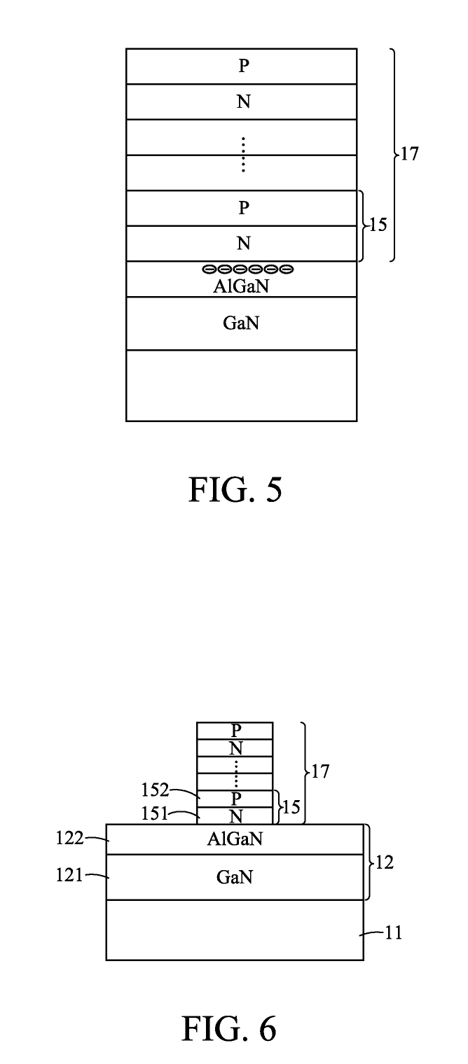

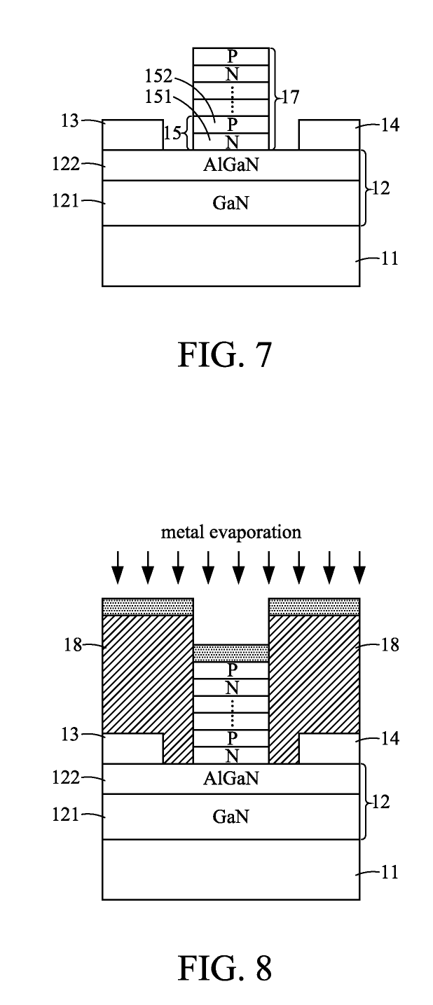

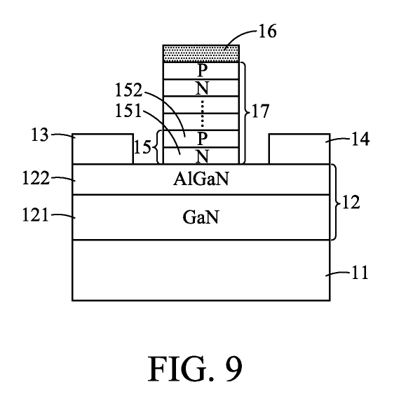

More particularly, the PN-junction stack according to the present invention can be integrated with the conventional depletion-mode or enhancement-mode field-effect transistors, so as to further increase the threshold voltages of the transistors. Here is an exemplary embodiment below. First of all, a semiconductor substrate 11 with a AlGaN/GaN heterostructure epitaxially grown thereon as a buffer layer 12 is provided, as shown in FIG. 3. By the photolithography process, a photoresist 18 is used to pattern the predetermined gate area. Next, the substrate 11 is subject to a CF₄ plasma treatment, as shown in FIG. 4, to let fluorine ions get into the AlGaN layer 122 to deplete carriers in the channel of a field-effect transistor; accordingly, the transistor becomes an enhancement-mode field-effect transistor. Further, the photoresist 18 is removed, and N-type and P-type semiconductor layers are alternatively deposited on the buffer layer/substrate 12/11 to form a PN-junction stack 17, as shown in FIG. 5. Thus, advantages of fluorine ions' depleting carriers in the transistor channel can be gained and further combined with performance of the PN-junction stack's 17 increasing the threshold voltages of the transistors. Then, the photolithography process is used to remove the PN-junction stack that is out of the predetermined gate area. In FIG. 6, the PN-junction stack 17 that is within the predetermined gate area, however, is reserved in order to control threshold voltages of the transistors. On the buffer layer 12, a source 13 and drain 14 are formed on the two respective sides of the PN-junction stack 17, as shown in FIG. 7. Then, the photolithography process is used to define a photoresist layer of the gate. As shown in FIG. 8, the substrate 11 is subject to metal evaporation to form ohmic contacts of the gate electrode and the PN-junction stack 17. Finally, by the lift-off process, the substrate 11 is subject to an acetone in ultrasonic vibration to strip the uncalled-for photoresist and metal film. The resultant enhancement-mode field-effect transistor with a PN-junction stack 17 is formed as shown in FIG. 9.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A method for fabricating an enhancement-mode HEMT comprising:
providing a semiconductor substrate that is with a buffer layer thereon;
forming a PN-junction stack on the buffer layer, wherein the PN-junction stack is composed of alternating layers of a P-type semiconductor and an N-type semiconductor;
etching the PN-junction stack that is out of the predetermined area of a gate;
forming a source on one side of the PN-junction stack and a drain on the other side thereof, wherein both the source and drain are formed on the buffer layer; and
forming the gate on the PN-junction stack.

2. The method of claim 1, wherein the PN-junction stack is separate from the source and drain.

3. The method of claim 1, wherein the semiconductor substrate is composed of GaAs, GaN, Si, SiC, or Sapphire.

4. The method of claim 1, wherein the buffer layer is of layered structure.

5. The method of claim 1, wherein the buffer layer is composed of GaAs, GaN, AlN, or AlGaN.

6. The method of claim 4, wherein the buffer layer is composed of AlGaN/GaN/AlN or GaN/AlGaN/AlN/GaN/AlN.

7. The method of claim 1, wherein the source and drain are composed of Ti, Al, W, Ni, or Au.

8. The method of claim 1, wherein the PN junction is composed of GaAs, GaN, AlN, or AlGaN.

9. The method of claim 1, wherein the gate is composed of Pb, Al, Ti, Au, WN₂, or mixtures thereof.
